(19) United States
(12) Patent Application Publication
(10) Pub. No.: US 2023/0154994 A1
(43) Pub. Date: May 18, 2023

(54) SEMICONDUCTOR DEVICE AND METHOD FOR MANUFACTURING SEMICONDUCTOR DEVICE

(71) Applicant: Fuji Electric Co., Ltd., Kanagawa (JP)

(72) Inventor: Takayuki SHIMATOU, Nagano (JP)

(73) Assignee: Fuji Electric Co., Ltd., Kanagawa (JP)

(21) Appl. No.: 17/958,881

(22) Filed: Oct. 3, 2022

(30) Foreign Application Priority Data
Nov. 12, 2021 (JP) 2021-184924

(51) Int. Cl. H01L 29/423; H01L 29/08; H01L 29/10; H01L 29/78; H01L 29/66

(52) U.S. Cl. CPC H01L 29/42368; H01L 29/0869; H01L 29/1095; H01L 29/7802; H01L 29/66712

(57) ABSTRACT

A semiconductor device includes a semiconductor substrate that includes a drift layer, a drain layer, a first well region and a second well region in the drift layer, a first source region selectively formed in the first well region, and a second source region selectively formed in the second well region; a gate insulating film selectively disposed on the semiconductor substrate and covering a portion of the drift layer sandwiched by the first well region and the second well region, the gate insulating film including a first portion and a second portion thicker than the first portion, arranged side by side so as to be laterally continuous to each other, the first portion being arranged on the first well region, the second portion being arranged on the second well region; and a gate electrode disposed on the gate insulating film that includes the first and second portions.

### BACKGROUND OF THE INVENTION

### Technical Field

The present invention relates to a semiconductor device and a method for manufacturing a semiconductor device.

### Background Art

Conventionally, it is known that when a semiconductor device such as an ASIC (Application Specific Integrated Circuit) is operated at high speed, the current waveform flowing during the drive transition period of the MOSFET (Metal-Oxide-Semiconductor Field-Effect Transistor) that constitutes the ASIC is smoothed to reduce electrical noise in order to improve the reliability of a semiconductor device (see, for example, Patent Document 1). It is also known that the switching frequency of a power conversion device incorporating the MOSFET can be increased by easing the rise and fall slopes of the current during switching of the MOSFET (see, for example, Patent Document 2).

### RELATED ART DOCUMENT

### Patent Document

Patent Document 1: Japanese Patent Application Laid-Open Publication No. 2000-12841
Patent Document 2: Japanese Patent Application Laid-Open Publication No. 2004-253765

### SUMMARY OF THE INVENTION

An object of the present invention is, in a MOS semiconductor device incorporating a large number of cell structures in order to reduce the on-resistance, to suppress an increase in di/dt at turn-on even when the cell density is increased by miniaturization.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a semiconductor device, comprising: a semiconductor substrate having an upper surface and a lower surface, the semiconductor substrate including: a drift layer on a side of the upper surface and a drain layer on a side of the lower surface, a first well region and a second well region selectively formed in the drift layer, each extending downwardly from the upper surface of the semiconductor substrate up to a first depth within the drift layer, the first well region and the second well region being arranged side by side with a portion of the drift layer sandwiched therebetween at the upper surface of the semiconductor substrate, a first source region selectively formed in the first well region so as to extend downwardly from the upper surface of the semiconductor substrate up to a second prescribed depth within the first well region, and a second source region selectively formed in the second well region so as to extend downwardly from the upper surface of the semiconductor substrate up to the second depth within the second well region; a gate insulating film selectively disposed on the upper surface of the semiconductor substrate, the gate insulating film covering the portion of the drift layer sandwiched by the first well region and the second well region, and having a first portion and a second portion arranged side by side so as to be laterally continuous to each other, the first portion being thinner than the second portion and arranged on, and in direct contact with, the first well region and the first source region, the second portion being arranged on, and in direct contact with, the second well region and the second source region; and a gate electrode disposed on the gate insulating film that includes the first and second portions.

Here, the first portion and the second portion of the gate insulating film may both be on the portion of the drift layer sandwiched by the first and second well regions.

Further, the second portion of the gate insulating film may cover a substantially entirety of the portion of the drift layer sandwiched by the first and second well regions,

In another aspect, the present invention provides a semiconductor device, comprising: a semiconductor substrate having an upper surface and a lower surface, the semiconductor substrate including: a drift layer on a side of the upper surface and a drain layer on a side of the lower surface, a first well region and a second well region selectively formed in the drift layer, each extending downwardly from the upper surface of the semiconductor substrate up to a first depth within the drift layer, the first well region and the second well region being arranged side by side with a portion of the drift layer sandwiched therebetween at the upper surface of the semiconductor substrate, a first source region selectively formed in the first well region so as to extend downwardly from the upper surface of the semiconductor substrate up to a second depth within the first well region, and a second source region selectively formed in the second well region so as to extend downwardly from the upper surface of the semiconductor substrate up to the second depth within the second well region; a gate insulating film selectively disposed on the upper surface of the semiconductor substrate, the gate insulating film having a first portion and a second portion arranged side by side laterally separated from each other, the first portion being thinner than the second portion and arranged on, and in direct contact with, the first well region and the first source region, the second portion being arranged on, and in direct contact with, the second well region and the second source region; and a first gate electrode disposed on the first portion of the gate insulating film and a second gate electrode disposed on the second portion of the gate insulating film.

A film thickness of the second portion of the gate insulating film may be 1.3 to 2 times a film thickness of the first portion of the gate insulating film.

In another aspect, the present invention provides a method for manufacturing a semiconductor device in a semiconductor substrate having an upper surface and a lower surface and including a drift layer on a side of the upper surface and a drain layer on a side of the lower surface, the method comprising: selectively forming well regions in the drift layer in the semiconductor substrate each extending downwardly from the upper surface of the semiconductor substrate up to a first depth within the drift layer; selectively forming source regions in the well regions, respectively, each extending downwardly from the upper surface of the semiconductor substrate up to a second depth within the corresponding well regions; forming a gate insulating film on the upper surface of the semiconductor substrate, the gate insulating film having a first portion and a second portion that are arranged laterally, the first portion being thinner than the second portion; forming a gate electrode on an upper surface of the gate insulating film; forming an interlayer insulating film so as to cover the gate electrode; forming a source electrode on an upper surface of the interlayer insulating film; and forming a drain electrode on the lower surface of the semiconductor substrate.

Here, the forming the gate insulating film may include: forming an insulating film on an entirety of the upper surface of the semiconductor substrate; selectively removing prescribed portions of the insulating film to form a pattern of the insulating films on the upper surface of the semiconductor substrate; and thereafter forming another insulating film on the pattern of the insulating films and on the upper surface of the semiconductor substrate on which the insulating film has been removed, thereby forming a composite insulating film as the gate insulating film having the first portion and the second portion that is thicker than the first portion.

In the step of forming the gate insulating film, a heat treatment may be performed in a state where a silicon oxide film has been selectively formed so that the semiconductor substrate is additionally oxidized to form the first portion and the second portion of the gate insulating film.

It should be noted that the above summary of the invention does not list all the features of the present invention. Subcombinations of these feature groups can also be inventions.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a schematic top view of a semiconductor device 100 according to a first embodiment of the present invention.

FIG. 2A is a diagram showing a cross section taken along the line A-A′ in FIG. 1;

FIG. 2B is an enlarged view showing another example of the area A in FIG. 2A.

FIG. 2C is an enlarged view showing another example of the area A in FIG. 2A.

FIG. 3A is a diagram showing the relationship between the gate voltage and the drain current of the semiconductor device 100.

FIG. 3B is a diagram showing the relationship between the drain current of the semiconductor device 100 and time;

FIG. 4 is a diagram illustrating an example of a flowchart of a method for manufacturing the semiconductor device 100.

FIG. 5 is a diagram for explaining an embodiment of the method for manufacturing the semiconductor device 100.

FIG. 6 is a diagram for explaining the embodiment of the method for manufacturing the semiconductor device 100.

FIG. 7 is a diagram for explaining the embodiment of the method for manufacturing the semiconductor device 100.

FIG. 8 is a diagram for explaining the embodiment of the method for manufacturing the semiconductor device 100.

FIG. 9 is a diagram for explaining the embodiment of the method for manufacturing the semiconductor device 100.

FIG. 10 is a diagram for explaining the embodiment of the method for manufacturing the semiconductor device 100.

FIG. 11 is a diagram for explaining the embodiment of the method for manufacturing the semiconductor device 100.

FIG. 12 is a diagram for explaining the embodiment of the method for manufacturing the semiconductor device 100.

FIG. 13 is a diagram for explaining the embodiment of the method for manufacturing the semiconductor device 100.

FIG. 14 is a diagram for explaining the embodiment of the method for manufacturing the semiconductor device 100.

FIG. 15 is a schematic cross-sectional view of a semiconductor device 101 according to a modified embodiment of the present invention;

FIG. 16 is a schematic cross-sectional view of a semiconductor device 110 according to a second embodiment of the present invention.

FIG. 17 is a schematic cross-sectional view of a semiconductor device 120 according to a third embodiment of the present invention.

FIG. 18 is a schematic cross-sectional view of a semiconductor device 130 according to a fourth embodiment of the present invention.

FIG. 19 is a schematic cross-sectional view of a semiconductor device 200 according to a comparative example.

FIG. 20A is a diagram showing the relationship between the gate voltage and the drain current of the semiconductor device 100 and the semiconductor device 200 of the comparative example.

FIG. 20B is a diagram showing the relationship between the drain current and time of the semiconductor device 100 and the semiconductor device 200 of the comparative example.

### DETAILED DESCRIPTION OF EMBODIMENTS

Hereinafter, the present invention will be described through embodiments of the invention, but the following embodiments do not limit the invention as set forth in the claims. Also, not all the combinations of features described in the embodiments are essential for the solution addressed by the invention. In this specification and the accompanying drawings, layers and regions prefixed with n or p mean that electrons or holes are majority carriers, respectively. Moreover, marks + and − attached to n and p mean that the impurity concentration is higher and lower than that of the layer or region not attached with them, respectively. When the notations of n and p including + and − are the same, it indicates that the concentrations are close, but the concentrations are not necessarily the same.

In the present specification and drawings, elements having substantially the same function and configuration are denoted by the same reference characters/numerals to omit redundant description, and elements that are not directly related to the present invention are not illustrated and omitted. Also, for elements in a single drawing having the same function and configuration, a representative element may be assigned a reference character/numeral, and the other elements may not be assigned with reference character/numeral.

In this specification, one side in a direction parallel to the depth direction of the semiconductor substrate is called “upper”, and the other side is called “lower”. One of the two main surfaces of a substrate, layer or other member is called the upper surface and the other surface is called the lower surface. The directions of “up” and “down” are not limited to the direction of gravity or the direction in which the semiconductor module is mounted.

In this specification, technical matters may be explained using the X-axis, Y-axis and Z-axis orthogonal coordinate axes. The Cartesian coordinate axes only specify the relative positions of the components and do not limit the orientation of the depicted object to any particular orientation. For example, the Z axis does not limit the dimension of the depicted object along the direction normal to the ground. Note that the +Z-axis direction and the —Z-axis direction are directions opposite to each other. When the Z-axis direction is described without indicating positive or negative, it means a direction parallel to the +Z-axis and −Z-axis. In this specification, orthogonal axes parallel to the upper and lower surfaces of the semiconductor substrate are defined as the X-axis and the Y-axis. Also, the axis perpendicular to the upper and lower surfaces of the semiconductor substrate is defined as the Z-axis. In this specification, the Z-axis direction may be referred to as the depth direction. Further, in this specification, a direction parallel to the upper and lower surfaces of the semiconductor substrate, including the X-axis and Y-axis, may be referred to as a horizontal direction.

In this specification, terms such as “identical” or “equal” may include cases where there is an error due to manufacturing variations or the like. The error is, for example, within 10%.

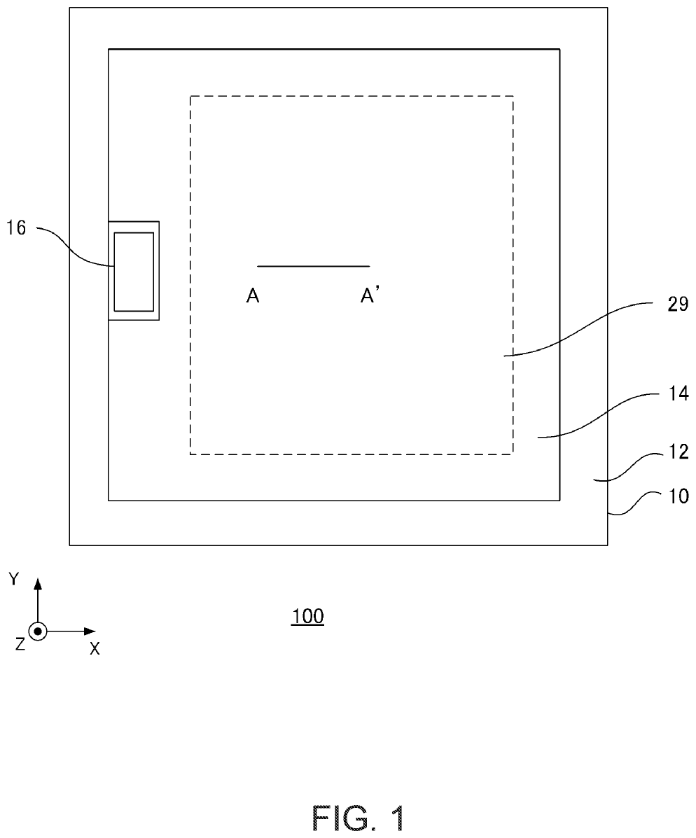

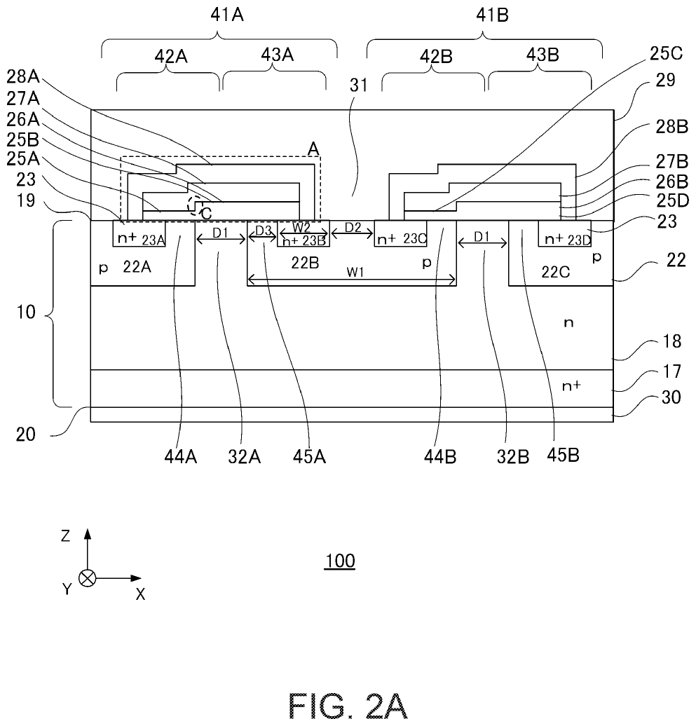

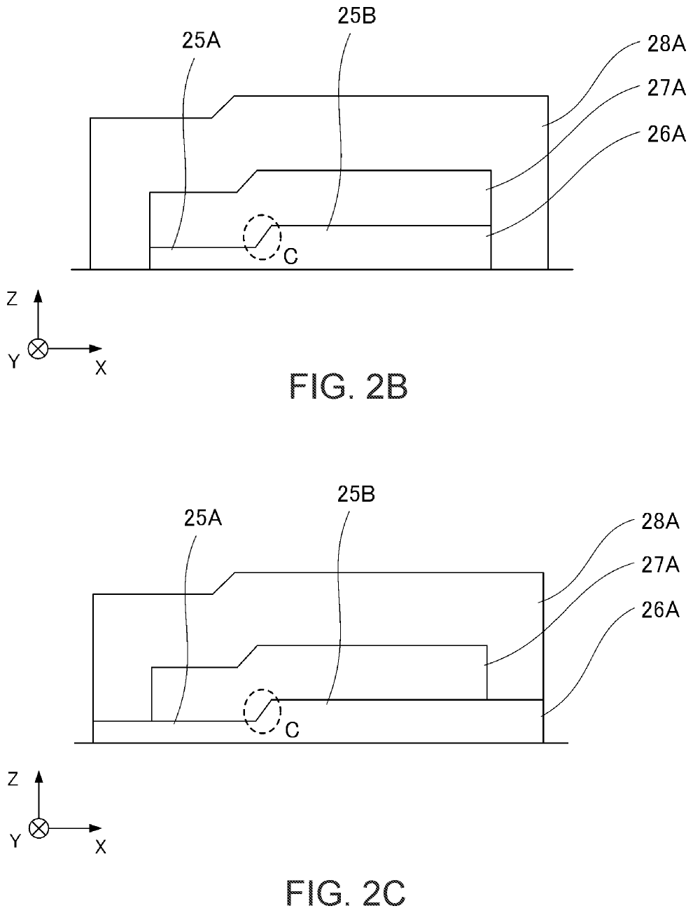

A first embodiment of the present invention will be described with reference to FIGS. 1-2C. FIG. 1 is a schematic top view of a semiconductor device 100 according to one embodiment of the present invention. A semiconductor device 100 is formed in a semiconductor substrate 10. The semiconductor substrate 10 may be a portion of a wafer that is substantially circular in top view shape. The material of the semiconductor substrate 10 is silicon, for example, but the material is not limited to silicon. The material of semiconductor substrate 10 may be silicon carbide (SiC). The semiconductor device 100 is singulated by dicing the semiconductor substrate 10.

A semiconductor device 100 has an active region 14 and a voltage withstanding structure 12. A transistor such as a MOSFET is formed in the active region 14. In this example, a vertical MOSFET is formed.

The voltage withstanding structure 12 is provided on the upper surface of the semiconductor device 100 so as to surround the active region 14. In this example, the voltage withstanding structure 12 is provided along the edge of the semiconductor substrate 10 when viewed from above. The voltage withstanding structure 12 has a guard ring, a field plate, or the like, and suppresses concentration of an electric field on the termination portion of the active region 14 so as to improve the breakdown voltage of the semiconductor device 100. The termination portion of the active region 14 is the boundary portion between the active region 14 of the active region 14 and the voltage withstanding structure portion 12.

A gate pad 16 is selectively provided on the upper surface of the semiconductor device 100 so as to be surrounded by the active region 14 and the voltage withstanding structure 12.

In FIG. 1, illustration of an insulating film for insulating the source electrode from the semiconductor substrate 10, and the like is omitted. Also, the illustration of a guard ring, a field plate, etc., provided in the voltage withstanding structure 12 is omitted. Also, the wiring that connects the gate pad 16 to the gate terminal of the vertical MOSFET provided in the active region 14 is omitted from the drawing. The reference numeral 29 is a source electrode.

FIG. 2A is a cross-sectional view taken along the line A-A′ in FIG. 1, showing two unit cells of a vertical MOSFET. The AA′ section is the XZ plane passing through the active region 14.

In FIG. 2A, the semiconductor device 100 includes an n⁺-type drain layer 17 and an n-type drift layer 18 in contact with the upper surface of the n⁺-type drain layer 17. In this specification, the stack of the n⁺-type drain layer 17 and the n-type drift layer 18 is referred to as the semiconductor substrate 10. The semiconductor substrate 10 has a top (upper) substrate surface 19 and a bottom (lower) substrate surface 20. The upper surface of the n-type drift layer 18 may be the substrate upper surface 19 of the semiconductor substrate 10. The upper substrate surface 19 may be the surface on which the gate structure of the vertical MOSFET is formed. A gate structure is a structure including, for example, at least one of a gate insulating film, a gate electrode, a source region, and a channel region.

A plurality of p-type well regions 22 are selectively provided on the substrate upper surface 19 side of the n-type drift layer 18. In FIG. 2A, the p-type well regions 22 includes p-type well regions 22A, 22B, and 22C. The p-type well regions 22A, 22B, 22C are arranged side by side in the X-axis direction.

A plurality of n⁺-type source region 23 are selectively provided on the substrate upper surface 19 side of the p-type well regions 22. Two n⁺-type source regions 23 may be provided side by side in the X-axis direction in one p-type well region 22. In FIG. 2A, n⁺-type source regions 23A, 23B, 23C, and 23D are provided as the n⁺-type source regions 23. The n⁺-type source regions 23A, 23B, 23C, and 23D are arranged side by side in the X-axis direction.

FIG. 2A shows two unit cells 41A and 41B of a vertical MOSFET device. The unit cell on the −X-axis direction side is called the unit cell 41A, and the unit cell on the +X-axis direction side is called the unit cell 41B. The unit cell 41A and the unit cell 41B have the same structure.

First, the unit cell 41A will be explained. The unit cell 41A includes two p-type well regions 22A and 22B adjacent to each other with the n-type drift layer 18 interposed therebetween. The two p-type well regions 22A and 22B are arranged in the X-axis direction. The p-type well region on the −X-axis direction side of the unit cell 41A is the p-type well region 22A, and the p-type well region on the +X-axis direction side is the p-type well region 22B.

An n⁺-type source region 23A is formed in the p-type well region 22A, and an n⁺-type source region 23B is formed in the p-type well region 22B.

Although not shown, another n⁺-type source region is formed on the −X-axis direction side within the p-type well region 22A, and the n⁺-type source region 23A shown in FIG. 2A is the n⁺-type source region on the +X-axis direction side within the p-type well region 22A. Similarly, in the p-type well region 22B, an n⁺-type source region 23B on the −X-axis direction side and a separate n⁺-type source region 23C on the +X-axis direction side are formed. In the first embodiment, the unit cell 41A includes the n⁺-type source region 23A, the p-type well regions 22A and 22B arranged side by side with the n-type drift layer 18 interposed therebetween, and the n⁺-type source region 23B.

Next, the structure of the unit cell 41A will be explained. A gate insulating film 26A is selectively provided on the substrate upper surface 19. The gate insulating film of the unit cell 41A is the gate insulating film 26A. One gate insulating film 26A may be provided in the unit cell 41A. The gate insulating film 26A is provided on the n⁺-type source region 23A, the p-type well region 22A, the n-type drift layer 18, the p-type well region 22B, and on the n⁺-type source region 23B.

The gate insulating film 26A has portions with different film thicknesses. The gate insulating film 26A has a gate insulating film 25A (“first portion”) and a gate insulating film 25B (“second portion”), and the film thickness of the gate insulating film 25A is thinner than the film thickness of the gate insulating film 25B. The gate insulating film 25A and the gate insulating film 25B are arranged in the X-axis direction and provided continuously. The thickness of the gate insulating film 25A may be 50 nm to 500 nm. The film thickness of the gate insulating film 25B may be 1.3 to 2 times the film thickness of the gate insulating film 25A. For example, the thickness of the gate insulating film 25A may be 80 nm, and the thickness of the gate insulating film 25B may be 120 nm. The film thickness of the gate insulating films 25A and 25B may be the thickness in the Z-axis direction at the portion where the upper surface is parallel to the X-axis.

In FIG. 2A, the gate insulating film 25A is in contact with the p-type well region 22A and part of the n⁺-type source region 23A. Also, the gate insulating film 25B is in contact with the p-type well region 22B, part of the n⁺-type source region 23B, and the n-type drift layer 18.

The gate insulating film 26A has a stepped portion C where the film thickness changes where the gate insulating film 25A and the gate insulating film 25B are continuous. The step portion C is located at the boundary between the p-type well region 22A and the n-type drift layer 18 in the X-axis direction when viewed from above. The reason why the position of the step portion C is set at the boundary position in the X-axis direction between the well region 22A and the n-type drift layer 18 is to provide a difference in the thickness of the gate insulating film between the two MOSFET portions, which will be described later.

In FIG. 2A, a gate electrode 27A is provided on the upper surface of the gate insulating film 26A. In this example, there are gate electrodes 27A and 27B as gate electrodes. The gate electrode of the unit cell 41A is the gate electrode 27A. The gate electrode 27B is the gate electrode of the unit cell 41B.

The gate electrode 27A is made of a conductive material such as polysilicon. In FIG. 2A, the film thickness of the gate electrode 27A may be, for example, 300 nm to 1000 nm. The film thickness of the gate electrode 27A may be the thickness in the Z-axis direction at the portion where the upper and lower surfaces of the gate insulating film 25A are parallel to the X-axis.

The film thickness of the gate electrode 27A may be uniform in the portion where the upper surface is parallel to the X-axis. Further, the gate electrode 27A may have a shape following the shape of the step portion C of the gate insulating film 26A so that the gate insulating film 26A is not exposed. Therefore, the gate electrode 27A has a step at a position corresponding to the step portion C of the gate insulating film 26A.

In FIG. 2A, an interlayer insulating film 28A is provided to cover the gate electrode 27A. In this example, there are interlayer insulating films 28A and 28B as interlayer insulating films. The interlayer insulating film of the unit cell 41A is the interlayer insulating film 28A. The interlayer insulating film 28B is an interlayer insulating film of the unit cell 41B.

The interlayer insulating films 28A, 28B may be formed of, for example, BPSG (Borophosphosilicate Glass), PSG (Phosphosilicate Glass), or the like. The interlayer insulating film 28 may be a laminate formed by forming HTO (High Temperature Oxide), NSG (None-doped Silicate Glass), or TEOS (tetraethoxysilane) film under BPSG (between BPSG and gate electrode 27).

In FIG. 2A, the film thickness of the interlayer insulating film 28 may be about 1 μm. The film thickness of the interlayer insulating film 28 may be the thickness in the Z-axis direction at the portion where the upper surface is parallel to the X-axis. The film thickness of the interlayer insulating film 28A may be uniform in the portions of the gate insulating films 25A and 25B parallel to the X-axis.

The interlayer insulating film 28A may have a shape following the shape of the step portion of the gate electrode 27A so that the gate electrode 27A is not exposed. Therefore, the interlayer insulating film 28A has a step at a position corresponding to the step portion C of the gate insulating film 26A.

As described above, a step portion C is formed in the gate insulating film 26A due to the difference in film thickness between the gate insulating films 25A and 25B. As a result, the gate electrode 27A stacked on the gate insulating film 26A is also stepped due to the step portion C. Similarly, the interlayer insulating film 28A stacked on the gate electrode 27A is also stepped due to the step portion C.

When forming the gate electrode 27A with a predetermined thickness on the gate insulating film 26A, the gate electrode 27A is also formed on the side surface of the stepped portion of the gate insulating film 26A so that the gate electrode is not interrupted at the stepped portion C of the gate insulating film 26A. Therefore, a stepped portion is also formed in the gate electrode 27A at a position shifted in the −X-axis direction from the stepped portion C of the gate insulating film 26A. Similarly, since the interlayer insulating film 28A also covers the side surface of the gate electrode 27A, a step in the interlayer insulating film 28A is formed at a position further shifted in the −X-axis direction from the step of the gate electrode 27A.

In FIG. 2A, the interlayer insulating film 28 is provided with a contact hole 31 that exposes the n⁺-type source regions 23 and the p type well region 22 through the opening. The −X-axis direction side of the contact hole 31 is the interlayer insulating film 28A, and the +X-axis direction side of the contact hole 31 is the interlayer insulating film 28B. That is, the boundary between the adjacent unit cells 41A and 41B may be the central portion of the contact hole 31 in the X-axis direction.

A source electrode 29 is provided so as to cover the interlayer insulating film 28. The source electrode 29 may be a metal film such as aluminum or an aluminum-based alloy (Al—Si, Al—Cu, Al—Si—Cu), and is made of Al—Si, for example. The film thickness of the source electrode 29 may be approximately 5 μm. The film thickness of the source electrode 29 may be the height from the bottom surface of the source electrode 29 in contact with the substrate upper surface 19 to the upper end of the source electrode 29. The interlayer insulating film 28 is provided between the source electrode 29 and the gate electrode 27 to insulate them. The source electrode 29 fills the contact hole 31. The source electrode 29 is electrically connected to the n⁺-type source regions 23 and p-type well region 22 through contact hole 31. A contact region (not shown) may be provided in a portion of the p-type well region 22 in contact with the source electrode 29 in order to reduce the contact resistance between the source electrode 29 and the p-type well region 22.

A drain electrode 30 in contact with the n⁺-type drain layer 17 is provided on the substrate lower surface 20. The drain electrode 30 is a laminate made of nickel (Ni), titanium (Ti), gold (Au), silver (Ag), aluminum (Al), or an aluminum-based alloy (Al—Si, Al—Cu, Al—Si—Cu), such as, for example, Ti/Ni/Au, Al/Ti/Ni/Au, etc.

A gate neck portion 32A is provided below the gate insulating film 26A. The gate neck portion 32A is part of the n-type drift layer 18 and is a portion sandwiched between two adjacent p-type well regions 22A and 22B. That is, the n⁺-type source region 23A, the p-type well region 22A, the gate neck portion 32A, the p-type well region 22B, and the n⁺-type source region 23B are arranged in the X-axis direction, and the gate insulating film 26A covers them.

As shown in FIG. 2A, the unit cell 41A has two MOSFET sections 42A and 43A. The −X-axis direction side of the gate neck portion 32A is the MOSFET section 42A, and the +X-axis direction side is the MOSFET section 43A. A channel portion 44A is a portion in which a channel is formed during operation of the MOSFET section 42A. A channel portion 45A is a portion in which a channel is formed during operation of the MOSFET section 43A. That is, MOSFET sections 42A and 43A are formed in one unit cell 41A, and channel portions of the MOSFET sections 42A and 43A are channel portions 44A and 45A, respectively. The gate insulating film of the MOSFET section 42A is the aforementioned gate insulating film 25A, and the gate insulating film of the MOSFET section 43A is the aforementioned gate insulating film 25B. Since the gate insulating films 25A and 25B have different film thicknesses, the MOSFET section 42A and the MOSFET section 43A have different film thicknesses of the gate insulating films. Therefore, the structure of the XZ plane of the unit cell 41 is laterally asymmetrical with respect to the center line extending in the Z-axis direction passing through the center of the gate neck portion 32.

The p-type well region 22, the n⁺-type source region 23, the gate insulating film 26, and the gate electrode 27 in FIG. 2A may extend for a predetermined length in the Y-axis direction. The predetermined length may be, for example, the same as the width of the active region 14 or may be shorter than the width of the active region 14.

Adjacent unit cells may share a p-type well region. In FIG. 2A, the adjacent unit cells 41A and 41B share the p-type well region 22B. Therefore, the p-type well region 22B may have a part of the unit cell 41A on the −X-axis direction side and a part of the unit cell 41B on the +X-axis direction side in the p-type well region 22B. The portion of the unit cell 41A on the −X-axis direction side may be the channel portion 45A and the n⁺-type source region 23B. The part of the unit cell 41 on the +X-axis direction side may be the channel part 44B and the n⁺-type source region 23C.

The unit cell 41A has two MOSFET sections 42A and 43A. The channel portion 44A of the MOSFET section 42A is formed in the p-type well region 22A. The channel portion 45A of the MOSFET section 43A is formed in the p-type well region 22B. The gate electrode 27A and interlayer insulating film 28A are provided in common to the gate insulating films 25A and 25B.

Similarly, the unit cell 41B has two MOSFET sections 42B and 43B. A channel portion 44B of the MOSFET section 42B is formed in the p-type well region 22B. A channel portion 45B of the MOSFET section 43B is formed in the p-type well region 22C. Gate electrode 27B and interlayer insulating film 28B are provided in common with gate insulating film 26B.

The gate insulating film 26B includes continuous gate insulating films 25C and 25D. The film thickness of the gate insulating film 25C is thinner than the film thickness of the gate insulating film 25D. The gate insulating films 25A and 25C, and the gate insulating films 25B and 25D have the same film thickness.

A channel portion 45A of the MOSFET section 43A of the unit cell 41A and a channel portion 44B of the MOSFET section 42B of the unit cell 41B are formed in the p-type well region 22B.

That is, two MOSFET sections are formed in the unit cell, one MOSFET section is formed in one well region and the other MOSFET section is formed in another well region, and these two MOSFET portions have a common gate electrode. Also, one MOSFET section of one unit cell and one MOSFET section of another unit cell are formed in one well region.

FIG. 2B is a diagram showing a modification of the region A portion indicated by the dotted line in FIG. 2A. The region A includes gate insulating film 26A, gate electrode 27A, and interlayer insulating film 28A. In FIG. 2B, the shape of the step portion C where the film thicknesses of the thin gate insulating film 25A and the thicker gate insulating film 25B change differs from the shape shown in FIG. 2A. That is, while the stepped portion C is step-shaped in FIG. 2A, it is slope-shaped in FIG. 2B. As long as a difference in film thickness between the gate insulating films 25A and 25B is provided, the shape of the step portion C may be modified this way. The width of the sloped step portion C may be in the range of 0 to 300 nm.

FIG. 2C shows another modification of area A in FIG. 2A. In FIG. 2C, in addition to the fact that the stepped portion C of the gate insulating film 26A is sloped, the −X-axis direction end of the gate insulating film 26A is aligned with the −X-axis direction end of the interlayer insulating film 28A with respect to the respective positions along the X-axis. The −X-axis direction end of the gate electrode 27A may be covered with the interlayer insulating film 28A. The −X-axis direction end of the gate electrode 27A may be located on the +X-axis direction side of the −X-axis direction end of the gate insulating film 26A. Similarly, the +X-axis direction end of the gate insulating film 26A may coincide with the +X-axis direction end of the interlayer insulating film 28A. The +X-axis direction end of the gate electrode 27A may be covered with the interlayer insulating film 28A. The +X-axis direction end of the gate electrode 27A may be located on the −X-axis direction side of the +X-axis direction end of the gate insulating film 26A.

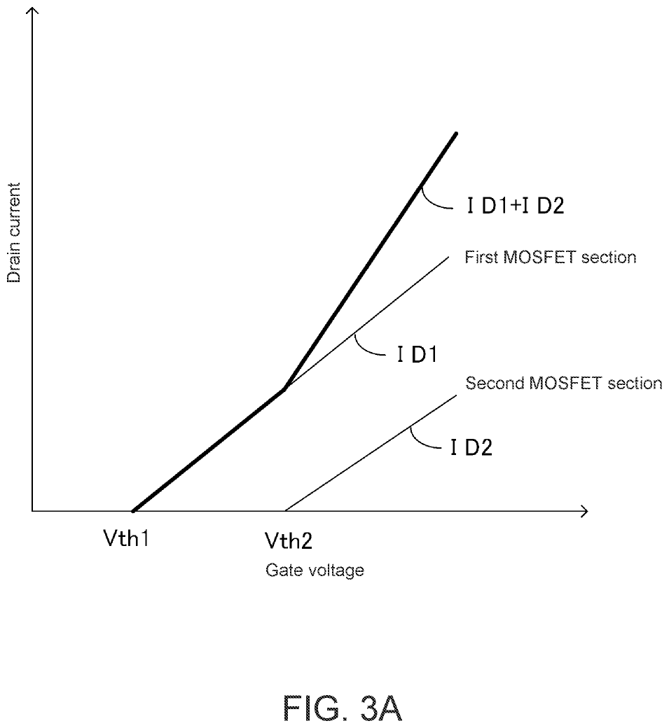

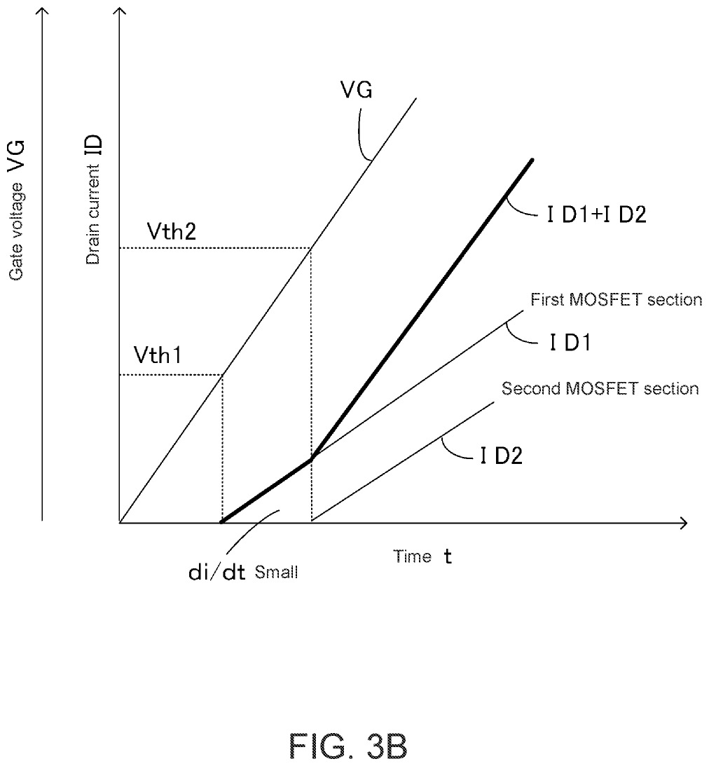

The operation of the semiconductor device 100 according to the first embodiment of the present invention will be explained. FIG. 3A is a diagram showing the relationship between the gate voltage and the drain current of the semiconductor device 100. In the semiconductor device 100, as described above, the gate insulating film 26A of the unit cell 41A includes the thin gate insulating film 25A and the thick gate insulating film 25B. That is, the film thickness of the gate insulating film 26A is thin above the channel portion 44A of the MOSFET section 42A and thick above the channel portion 45A of the MOSFET section 43A. Therefore, the MOSFET section 42A and the MOSFET section 43A have different threshold voltages. When the threshold voltage of the MOSFET section 42 is Vth1 and the threshold voltage of the MOSFET section 43 is Vth2, Vth1<Vth2 is satisfied.

In the semiconductor device 100, the same gate voltage is applied to the MOSFET section 42 and the MOSFET section 43. Therefore, as shown in FIG. 3A, the drain current ID1 of the semiconductor device 100 begins to flow in the MOSFET section 42 when the gate voltage exceeds Vth1. When the gate voltage exceeds Vth2, the drain current ID2 of the portion 43 starts to flow and joins ID1, and the resulting drain current becomes ID1+ID2. In FIG. 3A, the first MOSFET section is MOSFET section 42A and the second MOSFET section is MOSFET section 43A.

The channel widths of the two MOSFET sections of the unit cell may be the same. The channel width may be the width through which the drain current flows. If the film thicknesses of the gate insulating films of the two MOSFET portions of the unit cell are the same, then ID1=ID2 would be satisfied. But in the semiconductor device 100, because the film thicknesses of the gate insulating film 25A and the gate insulating film 25B are different, ID1 and ID2 are different. The drain currents of the MOSFET section 42A and the MOSFET section 43A of the unit cell 41A begin to flow at different timings, and the drain current of the semiconductor device 100 changes stepwise.

FIG. 3B is a diagram showing the relationship between the drain current of the semiconductor device 100 and time. In the semiconductor device 100, changes in drain current when a gate voltage is applied are shown. FIG. 3B also shows the gate voltage VG.

In the semiconductor device 100, a common gate voltage VG is applied to the MOSFET sections 42A and 43A of the unit cell 41A. When VG exceeds Vth1, the drain current ID1 of the MOSFET section 42 begins to flow, and when VG exceeds Vth2, the drain current ID2 of the MOSFET section 43 begins to flow and is added to ID1. In the semiconductor device 100, the rate of current increase (di/dt) near the beginning of drain current flow is determined by the drain current ID1 that flows only through the MOSFET section 42A of the unit cell 41A. Thus, in the semiconductor device 100, di/dt can be reduced by suppressing the current that starts flowing at Vth1.

In other words, near the point at which the drain current starts to flow, the current flows only in one MOSFET section of the unit cell, so di/dt becomes smaller than when the current starts to flow in two MOSFET sections of the unit cell.

In the present invention, the threshold voltages of the MOSFET section 42 and the MOSFET section 43 of the unit cell 41 are different, so that the waveform of the current that flows during the transition period of driving the MOSFET of the semiconductor device 100 becomes gentle. Therefore, by using the semiconductor device 100, electrical noise can be reduced, and it becomes easy to increase the speed and/or increase the number of functions in the semiconductor equipment on which the semiconductor device 100 is mounted.

A similar effect could be obtained by separately forming the gate electrode of the MOSFET section 42 and the gate electrode of the MOSFET section 43 and then applying separate voltages to the respective gate electrodes. But in such a case, voltage control and device structure become complicated.

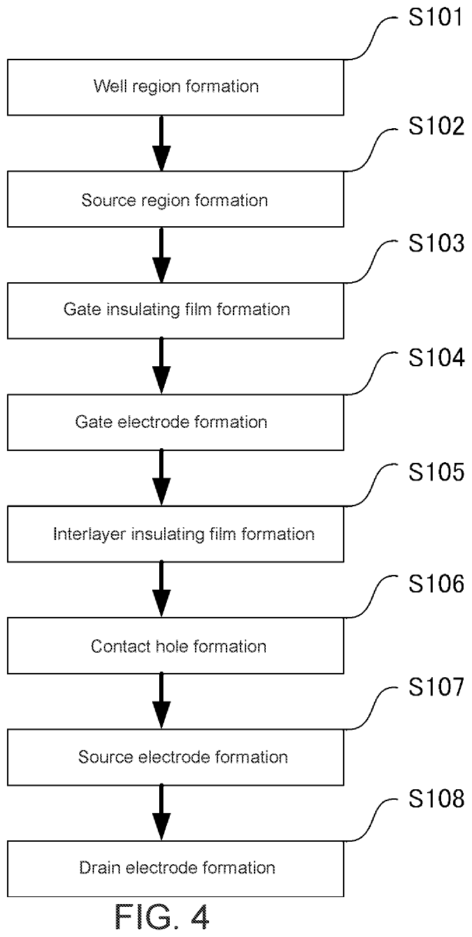

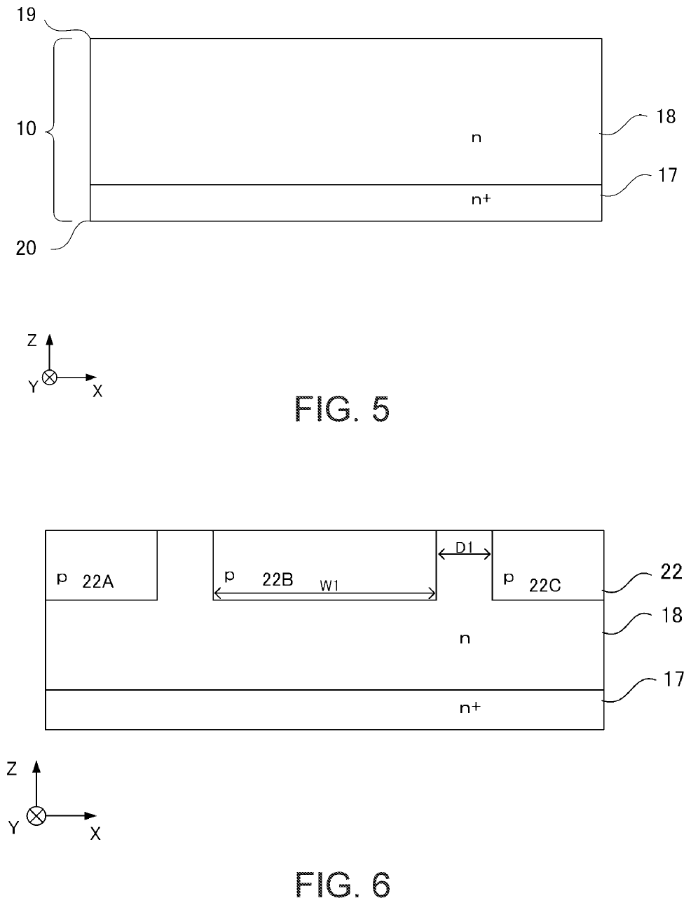

A method for manufacturing the semiconductor device 100 according to the first embodiment of the present invention will be described. FIG. 4 is a diagram illustrating an example of a flowchart of a method for manufacturing the semiconductor device 100 (see FIG. 2A). The method of manufacturing the semiconductor device 100 comprises a well region forming step S101, a source region forming step S102, a gate insulating film forming step S103, a gate electrode forming step S104, an interlayer insulating film forming step S105, a contact hole forming step S106, a source electrode forming step S107, and a drain electrode forming step S108. Below, the manufacturing method will be described along steps S101 to S108 in FIG. 4 with reference to FIGS. 5 to 14.

The semiconductor device 100 is formed in a semiconductor substrate 10 shown in FIG. 5. The semiconductor substrate 10 in this example may be a portion of a wafer having a substantially circular shape when viewed from above. A plurality of semiconductor devices 100 may be manufactured by dicing the semiconductor substrate 10 into individual pieces. The material of the semiconductor substrate 10 may be silicon (Si). The material of the semiconductor substrate 10 is not limited to silicon (Si). The material of semiconductor substrate 10 may be silicon carbide (SiC).

The semiconductor device 100 has an n-type drift layer 18 in contact with the upper surface of the n⁺-type drain layer 17. In this specification, the stack of the n⁺-type drain layer 17 and the n-type drift layer 18 is referred to as the semiconductor substrate 10. The semiconductor substrate 10 has a top substrate surface 19 and a bottom substrate surface 20.

The semiconductor substrate 10 may be formed by epitaxially growing the n-type drift layer 18 on the n⁺-type drain layer 17. In this case, the n⁺-type drain layer 17 may be the initial semiconductor substrate 10. The n⁺-type drain layer 17 and the n-type drift layer 18 contain n-type impurities. The n-type impurity amount of the n-type drift layer 18 is less than the n-type impurity amount of the n⁺-type drain layer 17. The n-type impurity is phosphorus (P) or arsenic (As), for example. The thickness of the n-type drift layer 18 may be, for example, 10 μm to 50 μm.

The semiconductor substrate 10 may be formed by providing the n⁺-type drain layer 17 in the n type drift layer 18 by ion implantation. In this case, the n-type drift layer 18 may be the initial semiconductor substrate 10. The impurity for forming the n⁺-type drain layer 17 may be phosphorus (P) or arsenic (As), for example. Before ion implantation, the n-type drift layer 18 may be ground from the back side so as to have a predetermined film thickness.

When the n-type drift layer 18 is formed by epitaxial growth, if the n-type drift layer 18 should be thick, it would take a long time to epitaxially grow the n-type drift layer 18. In such a case, therefore, it is more effective to form the n⁺-type drain layer 17 in the n-type drift layer 18 by ion implantation.

With reference to FIG. 6, the well region forming step S101 in FIG. 4 will be described. A resist film (not shown) having a predetermined pattern is formed on the substrate upper surface 19 by photolithography, and p-type impurity ions are selectively implanted into the semiconductor substrate 10 using the resist film as a mask. The p-type impurity is, for example, boron (B). After that, the resist film is removed and a predetermined heat treatment is performed to form the p-type well region 22. A plurality of p-type well regions 22 may be formed so as to be arranged in the X-axis direction. In FIG. 6, the p-type well regions 22A, 22B, and 22C are arranged from the −X-axis direction side.

Since some parts of the p-type well regions 22A and 22C are not shown in FIG. 6, the width in the X-axis direction of these regions is shown to be smaller than that of the p-type well region 22B, but they may have the same width. The width W1 of the p-type well region 22B in the X-axis direction may be, for example, 1 μm to 4 μm. A plurality of p-type well regions 22 are selectively formed side by side in the X-axis direction at predetermined intervals D1. The spacing D1 may be, for example, 0.3 μm to 1 μm.

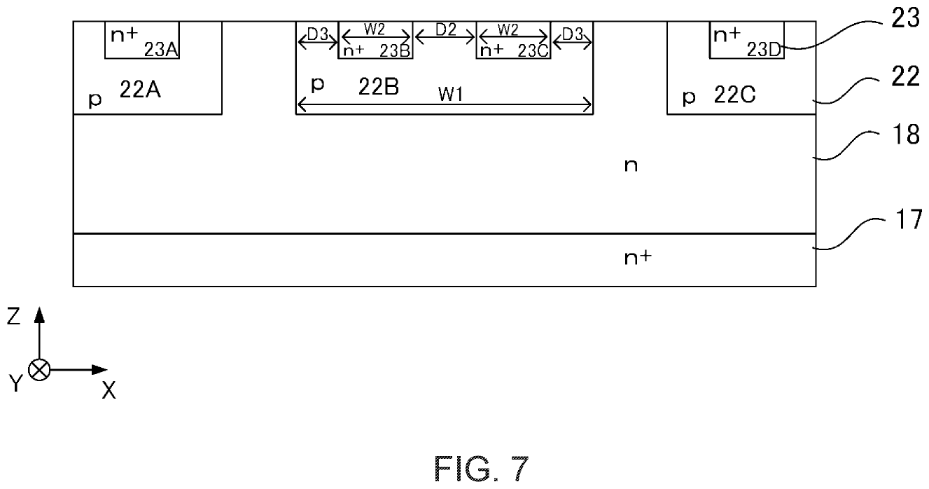

With reference to FIG. 7, the source region forming step S102 in FIG. 4 will be described. A resist film (not shown) having a predetermined pattern is formed on the substrate upper surface 19 by photolithography, and n-type impurity ions are selectively implanted into the p-type well region 22 using the resist film as a mask. The n-type impurity is phosphorus (P), for example. After that, the resist film is removed and a predetermined heat treatment is performed to form a plurality of n⁺-type source regions 23. Two n⁺-type source regions 23 may be formed side by side in the X-axis direction in one p-type well region 22. In FIG. 7, the n⁺-type source regions 23A, 23B, 23C, and 23D are arranged from the −X-axis direction side. In FIG. 7, the other n⁺-type source region on the −X-axis direction side in the p-type well region 22A and the other n⁺-type source region on the +X-axis direction side in the p-type well region 22C are not shown.

The widths in the X-axis direction of the n⁺-type source regions 23A, 23B, 23C, and 23D may be the same. The width W2 in the X-axis direction of the n⁺-type source region 23 may be, for example, 0.3 μm to 1 μm. Two n⁺-type source regions 23 are selectively formed in one p-type well region 22 side by side in the X-axis direction with a predetermined interval D2. The spacing D2 may be, for example, 0.3 μm to 1 μm.

The distance from the −X-axis direction end of the p-type well region 22 to the −X-axis direction end of the n⁺-type source region 23 on the −X-axis direction side in the p-type well region 22 may have a spacing D3. The spacing D3 may be, for example, 0.1 μm to 1 μm. The distance from the +X-axis direction end of the p-type well region 22 to the +X-axis direction end of the n⁺-type source region 23 on the +X-axis direction side in the p-type well region 22 may also have the spacing D3.

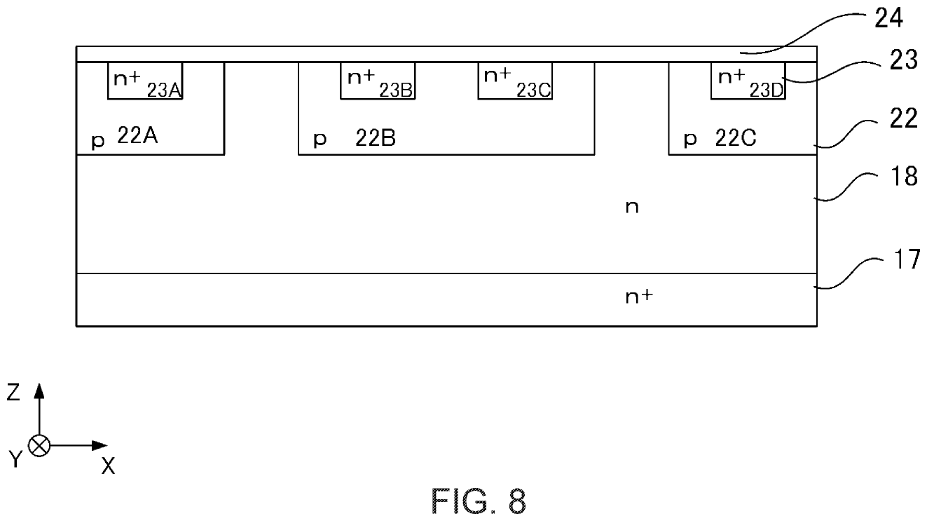

With reference to FIGS. 8 to 10, the gate insulating film formation step S103 in FIG. 4 will be described. In the gate insulating layer forming step S103, a silicon oxide layer is formed in at least two steps. In FIG. 8, as the first silicon oxide film formation, a silicon oxide film 24 is formed on the entire surface of the substrate upper surface 19. The silicon oxide film 24 may be formed by thermally oxidizing the semiconductor substrate 10. The silicon oxide film 24 may be formed by a CVD (Chemical Vapor Deposition) method instead.

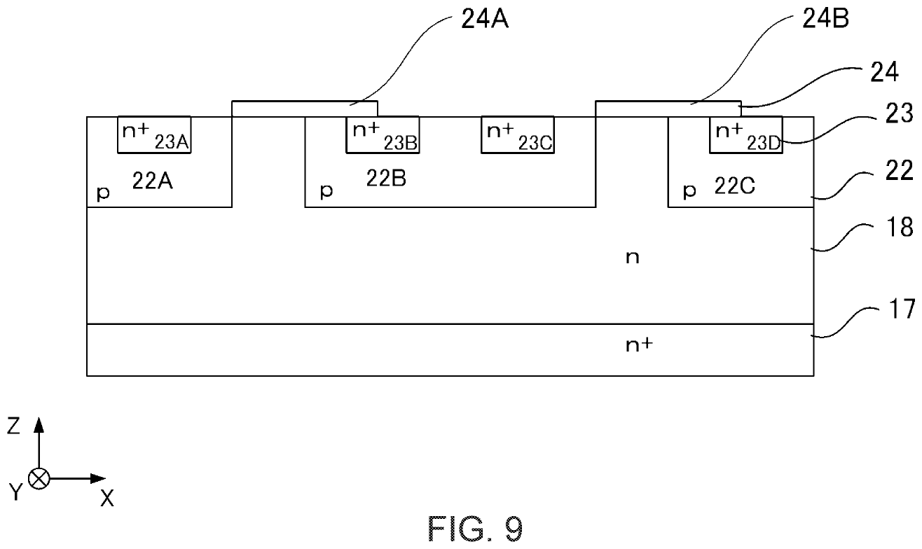

Next, in FIG. 9, the silicon oxide film 24 is selectively left on the substrate upper surface 19 by photolithography and etching. The silicon oxide films 24 are arranged in the X-axis direction. In FIG. 9, the silicon oxide film 24 has a silicon oxide film (island) 24A on the −X-axis direction side and a silicon oxide film (island) 24B on the +X-axis direction side. The silicon oxide film 24A may be in contact with the upper surfaces of the n-type drift layer 18, the p-type well region 22B and the n⁺-type source region 23B. The silicon oxide film 24B may be in contact with the upper surfaces of the n-type drift layer 18, the p-type well region 22C and the n⁺-type source region 23D.

The end of the silicon oxide film 24A on the −X-axis direction may be on the boundary between the p-type well region 22A and the n-type drift layer 18 in the X-axis direction when viewed from above. The end of the silicon oxide film 24A on the +X-axis direction side may be on the n⁺-type source region 23B when viewed from above. Similarly, the −X-axis direction end of the silicon oxide film 24B may be on the X-axis direction boundary between the p-type well region 22B and the n-type drift layer 18 when viewed from above. The end of the silicon oxide film 24B on the +X-axis direction side may be on the n⁺-type source region 23D when viewed from above.

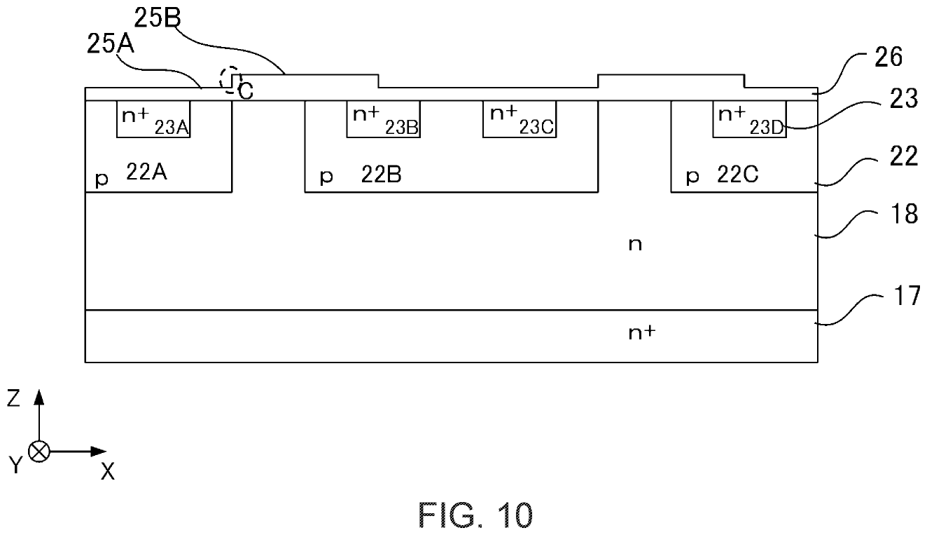

Next, in FIG. 10, a silicon oxide film is formed on the upper surface 19 of the substrate as a second silicon oxide film. This silicon oxide film may be formed by thermally oxidizing the semiconductor substrate 10. The silicon oxide film may be formed by the CVD method instead. At this time, the film thickness of the silicon oxide film in the region where the silicon oxide film 24 has been formed in advance becomes thicker than in the other regions. When the second silicon oxide film is formed by CVD, in order to improve the interface between the gate insulating film 26 and the semiconductor substrate, thermal oxidation is preferably performed after forming the second silicon oxide film by CVD. Oxygen atoms in the atmosphere and silicon atoms in the semiconductor substrate react with each other by thermal oxidation to form a silicon oxide film, and therefore, a clean interface is formed between the silicon oxide film and the semiconductor substrate in this way.

Through the gate insulating film formation step S103 described above, the gate insulating film 26 including the thick gate insulating film 25B and the gate insulating film 25A thinner than the gate insulating film 25B is formed. The gate insulating film 26 is formed with a stepped portion C where the film thicknesses of the gate insulating film 25A and the gate insulating film 25B change. The stepped portion C may be located at the boundary between the p-type well region 22A and the n-type drift layer 18 in the X-axis direction when viewed from above. The reason why the position of the stepped portion C is set at the boundary position of the well region 22A and the n-type drift layer 18 in the X-axis direction is to provide a difference in thickness of the gate insulating film between the two MOSFET portions. However, as will be described below, the stepped portion C may be located at a different location as long as it provides different effective gate insulating film thicknesses/thresholds above the respective channel regions. The stepped portion C may have a predetermined width in the X-axis direction. The predetermined width in the X-axis direction may range, for example, from 0 to 300 nm.

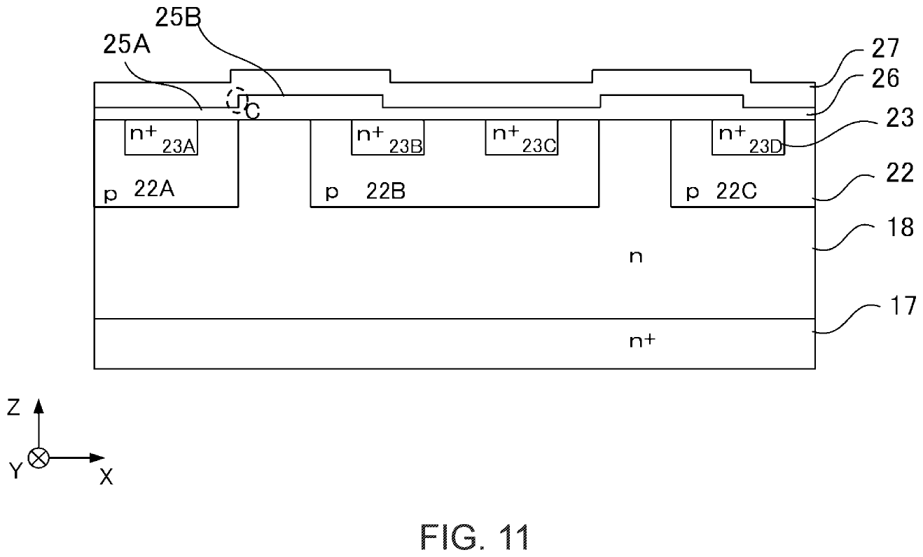

Next, referring to FIG. 11, the gate electrode forming step S104 of FIG. 4 will be described. A gate electrode layer 27 is formed on the upper surface of the gate insulating film 26. A gate electrode layer 27 covers the gate insulating film 26.

The underlying gate insulating film 26 includes a thin gate insulating film 25A and a gate insulating film 25B thicker than the gate insulating film 25A, and has the stepped portion C in a portion where the film thickness changes. Thus, a step may be formed in the gate electrode layer 27 at a position corresponding to the step portion C of the gate insulating film 26 when viewed from above. The stepped portion of the gate electrode layer 27 may follow the shape of the stepped portion C of the gate insulating film 26 so that the gate insulating film 26 is not exposed.

The gate electrode layer 27 may be made of a conductive material such as polysilicon. The gate electrode layer 27 may be formed by CVD. The film thickness of the gate electrode layer 27 may be the height in the Z-axis direction at the portion where the upper and lower surfaces are parallel to the X-axis. The film thickness of the gate electrode layer 27 is, for example, 300 to 1000 nm.

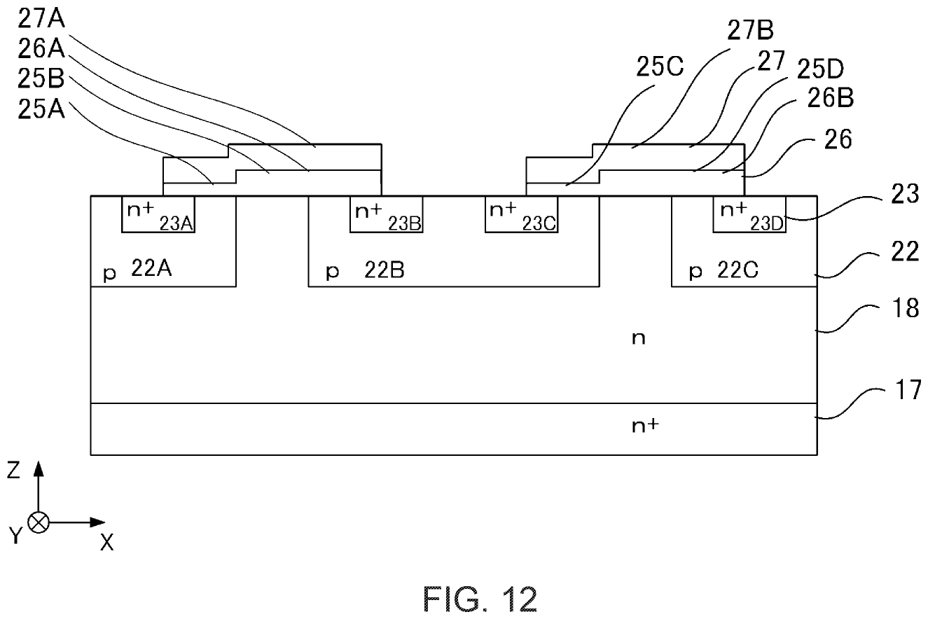

Next, in FIG. 12, a plurality of stacked structures of the gate insulating film 26 and the gate electrode 27 are selectively formed by photolithography and etching. The stacked structures of the gate insulating film 26 and the gate electrode 27 may be arranged in the X-axis direction. The stacked structure of the gate insulating film 26 and the gate electrode 27 may have a stacked structure of the gate insulating film 26A and the gate electrode 27A on the −X-axis direction side and a stacked structure of the gate insulating film 26B and the gate electrode 27B on the +X-axis direction side.

The stacked structure of the gate insulating film 26 and the gate electrode 27 may cover the adjacent two p-type well regions 22 and part of one source region provided in each p-type well region 22 and the n-type drift layer 18. That is, the stacked structure of the gate insulating film 26A and the gate electrode 27A may cover the p-type well region 22A, the n⁺-type source region 23A, the p-type well region 22B, the n⁺-type source region 23B, and the n-type drift layer 18. Similarly, the stacked structure of the gate insulating film 26B and the gate electrode 27B may cover the p-type well region 22B, the n⁺-type source region 23C, the p-type well region 22C, the n⁺-type source region 23D, and the n-type drift layer 18.

In the stacked structure of the gate insulating film 26 and the gate electrode 27, the edge of the gate insulating film 26 on the −X-axis direction and the edge of the gate electrode 27 on the −X-axis direction may substantially coincide when viewed from above. The end of the gate insulating film 26 on the +X-axis direction and the end of the gate electrode 27 on the +X-axis direction may substantially coincide when viewed from above. This way, for the gate insulating film 26 and the gate electrode 27, the ends on the −X-axis direction and the ends on the +X-axis direction are made substantially coincident, which makes it possible to use the same single etching mask to make the structure.

The end of the gate insulating film 26 on the −X-axis direction may be on the n⁺-type source region 23 on the +X-axis direction side in the p-type well region 22 on the −X-axis direction side when viewed from above. The +X-axis direction end of the gate insulating film 26 may be on the −X-axis direction side n⁺-type source region 23 in the +X-axis direction side p-type well region 22 when viewed from above. In other words, the end of the gate insulating film 26A on the −X-axis direction may be on the n⁺-type source region 23A on the +X-axis direction side in the p-type well region 22A on the −X-axis direction side when viewed from above. The +X-axis direction end of the gate insulating film 26A may be on the −X-axis direction side n⁺-type source region 23B in the +X-axis direction side p-type well region 22B when viewed from above.

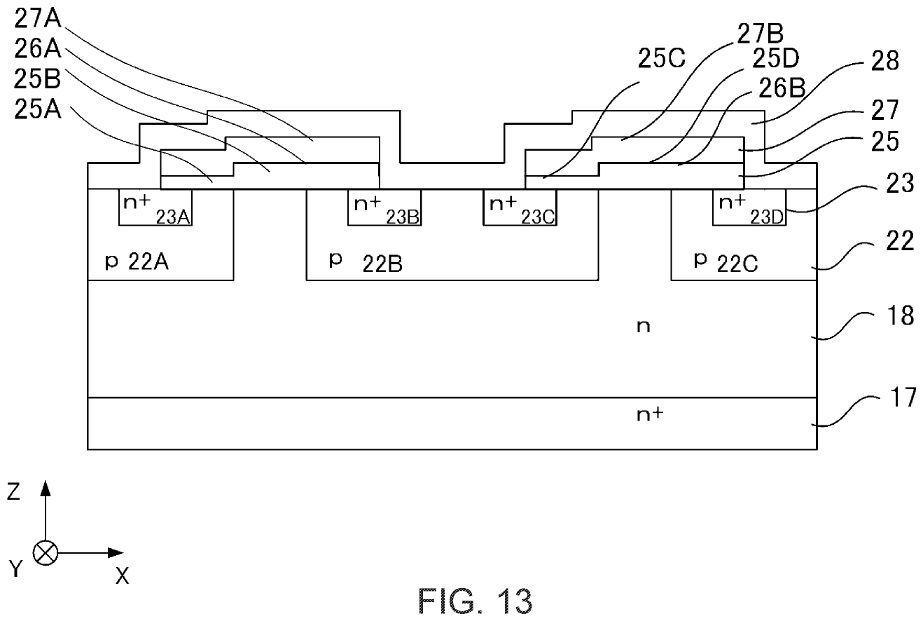

Next, referring to FIG. 13, the interlayer insulating film forming step S105 of FIG. 4 will be described. An interlayer insulating film 28 is formed to cover the gate electrode 27. The interlayer insulating film 28 may be formed of, for example, BPSG, PSG (Phosphorus Silicate Glass), or the like. The interlayer insulating film 28 may instead be, for example, a laminate formed by forming HTO (High Temperature Oxide), NSG (None-doped Silicate Glass), or TEOS (tetraethoxysilane) film under BPSG (between BPSG and gate electrode 27). The film thickness of the interlayer insulating film 28 may be, for example, 1 μm. The film thickness of the interlayer insulating film 28 may be the thickness in the Z-axis direction of the portion where the upper and lower surfaces are parallel to the X-axis.

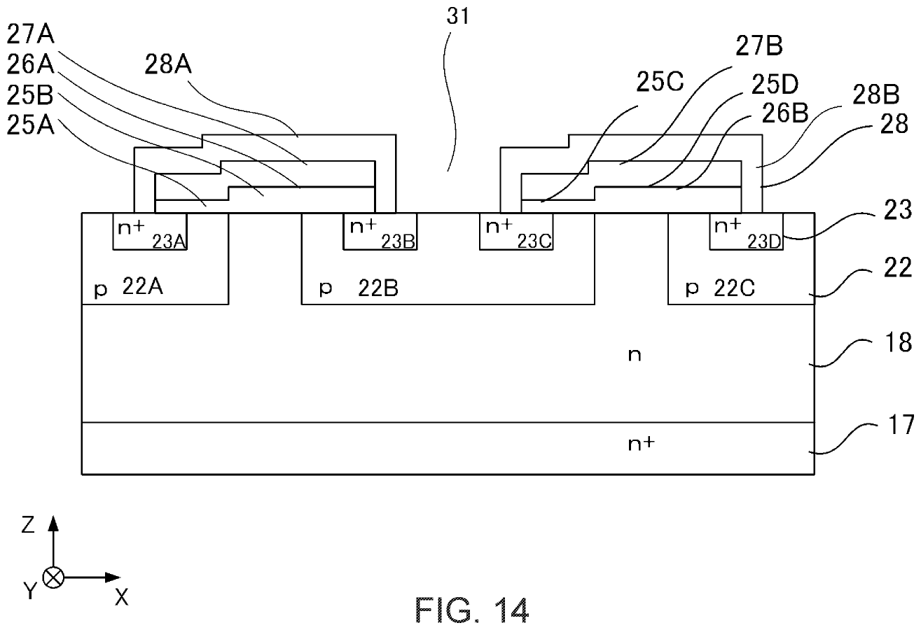

Next, with reference to FIG. 14, the contact hole forming step S106 of FIG. 4 will be described. A contact hole 31 is formed in the interlayer insulating film 28 by photolithography and etching. The contact hole 31 may expose n⁺-type source region 23 and p type well region 22. In FIG. 14, the contact hole 31 exposes n⁺-type source region 23B, p-type well region 22B, and n⁺-type source region 23C.

The contact hole 31 may be formed by anisotropic dry etching. After forming the contact hole 31, the interlayer insulating film 28 may be reflowed. But the reflow process may not be necessary depending on the specification, device design, or the like. As shown in FIG. 14, the end faces of the gate insulating film 26 and gate electrode 27 may be covered with the interlayer insulating film 28.

In FIG. 14, the −X-axis direction side of the contact hole 31 is the interlayer insulating film 28A, and the +X-axis direction side of the contact hole 31 is the interlayer insulating film 28B.

If the cross-sectional structure shown in FIG. 2C is to be made, after the gate electrode 27 is formed on the upper surface of the gate insulating film 26, only the polysilicon is etched by photolithography and etching, and the gate insulating film is not etched. After that, an interlayer insulating film is formed on the entire upper surfaces of the gate insulating film 26 and the gate electrode 27, and then the interlayer insulating film 28 and the gate insulating film 26 are etched by photolithography and etching in the same process to form the contact hole 31.

With reference to FIG. 2A, the source electrode forming step S107 and the drain electrode forming step S108 will be described. First, in the source electrode forming step S107, the source electrode 29 is formed to cover the interlayer insulating film 28. The source electrode 29 may be a metal film made of, aluminum or an alloy containing aluminum as a main component (Al—Si, Al—Cu, Al—Si—Cu), for example. The source electrode 29 may be formed by sputtering. The source electrode 29 may be formed on the interlayer insulating film 28 via a barrier metal (not shown). The barrier metal may be a titanium film (Ti), a titanium nitride film (TiN), or a laminated film of these (for example, Ti/TiN, etc.). The barrier metal may be formed by sputtering. The source electrode 29 may fill the contact hole 31. Source electrode 29 is electrically connected to n⁺-type source region 23 and p-type well region 22.

In the drain electrode forming step S108, the drain electrode 30 is formed to be in contact with the drain layer on the bottom surface 20 of the substrate. The drain electrode 30 is made of nickel (Ni), titanium (Ti), gold (Au), silver (Ag), aluminum (Al), or an alloy containing aluminum as a main component (Al—Si, Al—Cu, Al—Si—Cu) or the like (for example, Ti/Ni/Au, Al/Ti/Ni/Au, etc.). The drain electrode 30 may be formed by sputtering. Next, a heat treatment is performed to form an ohmic contact between the n⁺-type drain layer 17 and the drain electrode 30. After the source electrode forming step S107 and before the drain electrode forming step S108, the substrate lower surface 20 side may be ground. The manufacturing steps described thus far complete the semiconductor device 100.

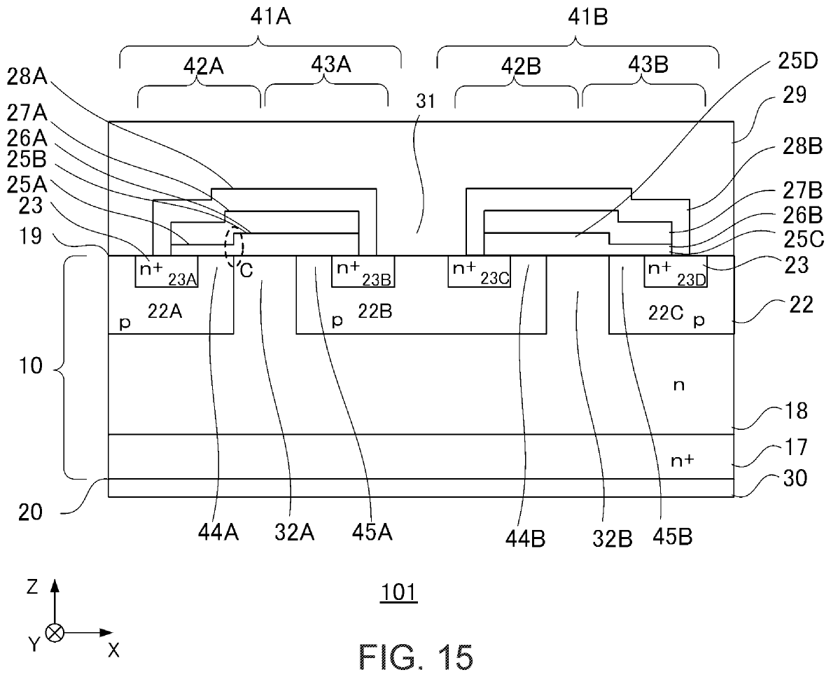

A semiconductor device 101 according to a modified example of the semiconductor device 100 will be described with reference to FIG. 15. In the semiconductor device 101, the gate insulating films 26A and 26B have different shapes in the adjacent unit cells 41A and 41B, as follows. In the gate insulating film 26A, a thin gate insulating film 25A and a gate insulating film 25B thicker than the gate insulating film 25A are provided, and the gate insulating film 25A is arranged on the —X axis direction side and the gate insulating film 25B is arranged on the +X axis direction side. On the other hand, in the gate insulating film 26B, a thin gate insulating film 25C and a gate insulating film 25D with a thicker film thickness than the gate insulating film 25C are provided. The thinner gate insulating film 25C is arranged on the +X-axis direction side, and the thicker gate insulating film 25D is arranged on the −X-axis direction side. The semiconductor device 101 may be made in the same manufacture method as the semiconductor device 100. In the semiconductor device 101, like the semiconductor device 100, the effect of reducing di/dt can be obtained.

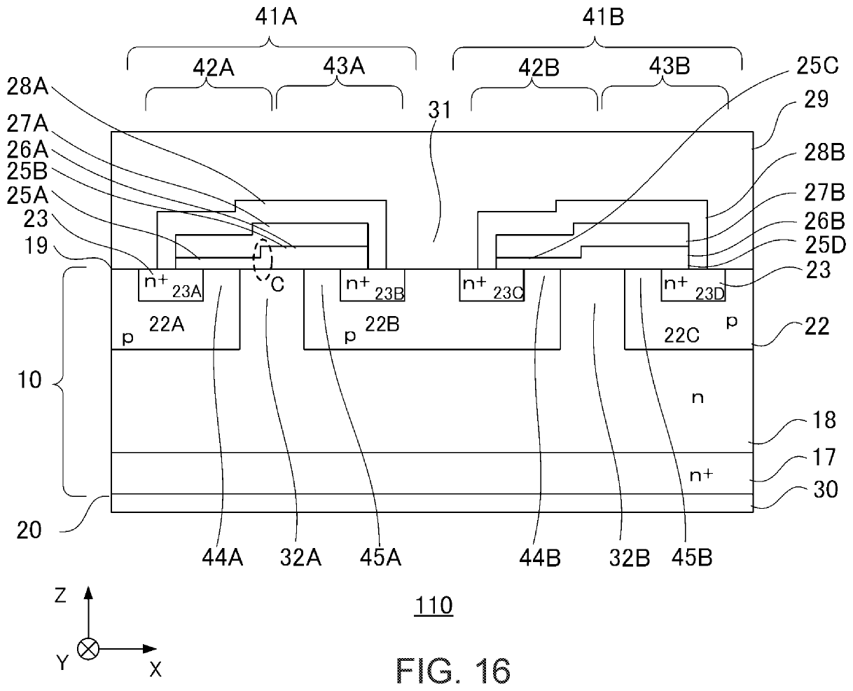

A second embodiment of the present invention will be described with reference to FIG. 16. The difference between the semiconductor device 110 of the second embodiment and the semiconductor device 100 of the first embodiment is that the step portion C of the gate insulating film 26A is located above the gate neck portion 32A. The gate insulating film 26A is composed of a thin gate insulating film 25A and a gate insulating film 25B thicker than the gate insulating film 25A. The gate insulating film 25A and the gate insulating film 25B may be arranged in the X-axis direction. The gate insulating film 25A and gate insulating film 25B are continuous. A step portion C is provided at a portion where the film thicknesses of the gate insulating film 25A and the gate insulating film 25B change. The gate insulating film 25A is provided on the upper surfaces of the n⁺-type source region 23A, the p-type well region 22A, and the n-type drift layer 18. The gate insulating film 25B is provided on the upper surfaces of the n⁺-type source region 23B, the p-type well region 22B, and the n-type drift layer 18. The step portion C of the gate insulating film 26A is located on the gate neck portion 32A when viewed from above. In the unit cell 41A, the gate insulating film on the upper surface of the channel portion 44A of the MOSFET portion 42A is made of the gate insulating film 25A, and the gate insulating film on the upper surface of the channel portion 45A of the MOSFET portion 43A is made of the gate insulating film 25B.

In the semiconductor device 110 of the second embodiment, as in the case of the semiconductor device 100 of the first embodiment, the thickness of the gate insulating film 25A on the channel portion 44 is smaller than the thickness of the gate insulating film 25B on the channel portion 45. Therefore, the MOSFET section 42 and the MOSFET section 43 have different thresholds, making it possible to adjust the di/dt characteristics. In addition, in the semiconductor device 110 of the second embodiment, as compared with the semiconductor device 100, the capacitance between the gate and the drain is increased. Therefore, dv/dt at turn-off is also reduced and the associated noise is reduced.

The method for manufacturing the semiconductor device 110 according to the second embodiment is the same as the method for manufacturing the semiconductor device 100 according to the first embodiment. Therefore, the description thereof will be omitted.

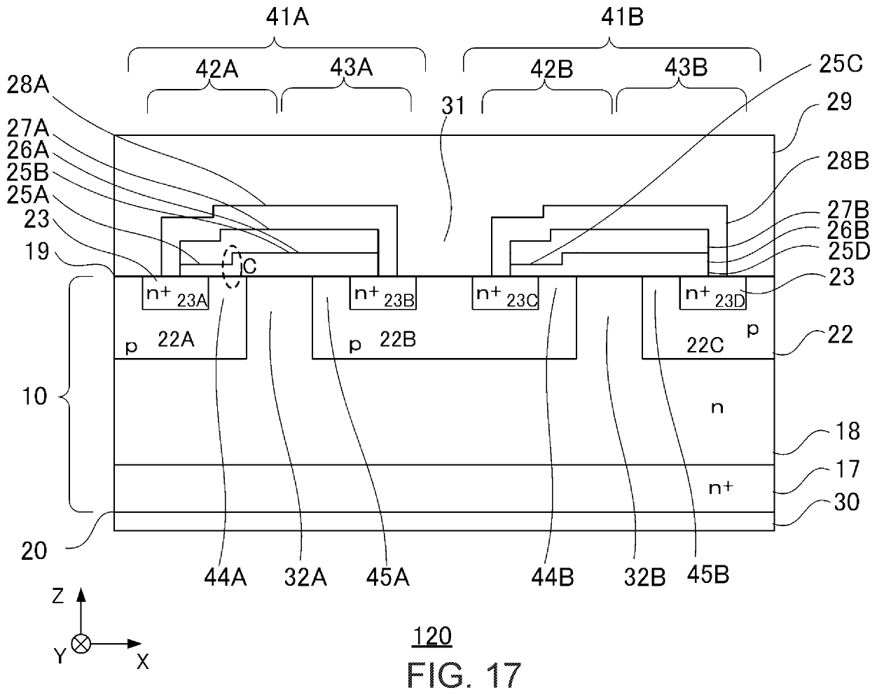

A third embodiment of the present invention will be described with reference to FIG. 17. The difference between the semiconductor device 120 of the third embodiment and the semiconductor device 100 of the first embodiment is that the step portion C of the gate insulating film 26A is located above the p-type well region 22A.

The gate insulating film 26A is composed of a thin gate insulating film 25A and a gate insulating film 25B thicker than the gate insulating film 25A. The gate insulating film 25A and the gate insulating film 25B may be arranged in the X-axis direction. The gate insulating film 25A and the gate insulating film 25B may be continuous. A step portion C is provided at a portion where the film thicknesses of the gate insulating film 25A and the gate insulating film 25B change. The gate insulating film 25A is provided on the upper surfaces of the n⁺-type source region 23A and the p-type well region 22A. The gate insulating film 25B is provided on the upper surfaces of the n⁺-type source region 23B, the p-type well region 22B, the n-type drift layer 18, and the p-type well region 22A. That is, the step portion C is located above the p-type well region 22A when viewed from above. In the unit cell 41A, the gate insulating film on the upper surface of the channel portion 44A of the MOSFET portion 42A is composed of the gate insulating film 25A and the gate insulating film 25B, and the gate insulating film on the upper surface of the channel portion 45A of the MOSFET portion 43A is the gate insulating film 25B.

In the semiconductor device 120 of the third embodiment, the gate insulating film 25A and the gate insulating film 25B are provided on the channel portion 44A. Therefore, as in the first embodiment, the MOSFET section 42 and the MOSFET section 43 have different thresholds, making it possible to adjust the di/dt characteristics. In addition, in the semiconductor device 120 of the third embodiment, since the stepped portion C of the gate insulating film 25 is located above the p-type well region 22A when viewed from above, the capacitance between the gate and the source is made smaller than that of the semiconductor device 100. As a result, Qg (the amount of electric charges) can be suppressed and the driving loss can be reduced.

The method for manufacturing the semiconductor device 120 according to the third embodiment is the same as the method for manufacturing the semiconductor device 100 according to the first embodiment. Therefore, the description thereof will be omitted.

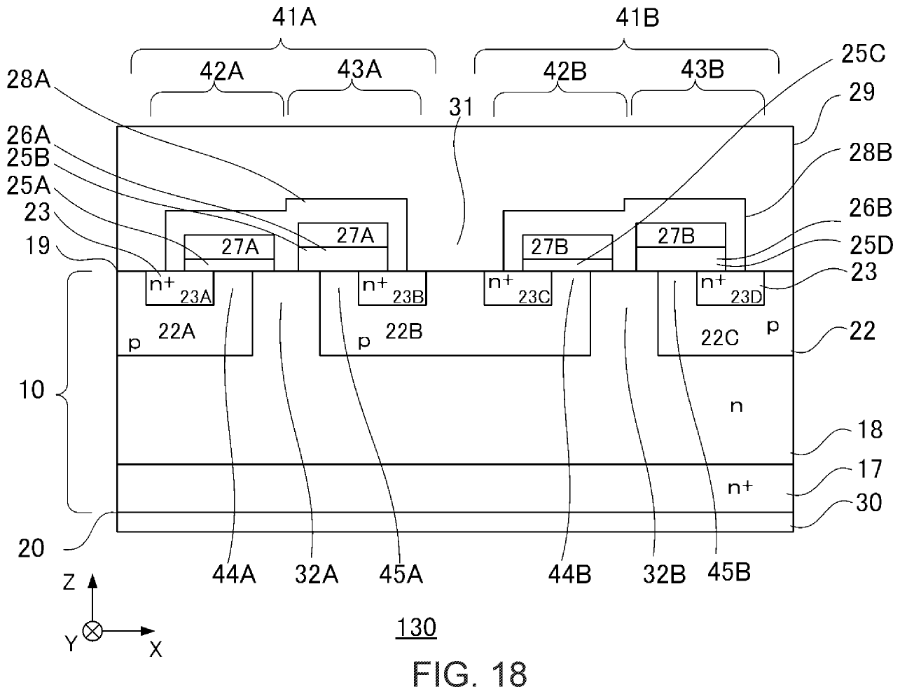

A fourth embodiment of the present invention will be described with reference to FIG. 18. The difference between the semiconductor device 130 of the fourth embodiment and the semiconductor device 100 of the first embodiment is that the gate insulating film 26 and the gate electrode 27 are separated above the gate neck portion 32 by the interlayer insulating film 28.

In the semiconductor device 130, a thin gate insulating film 25A and a gate insulating film 25B thicker than the gate insulating film 25A are divided by the interlayer insulating film 28A. Gate electrodes 27A of the semiconductor device 130 are formed on the gate insulating film 25A and the gate insulating film 25B. The gate electrodes 27A are separated by an interlayer insulating film 28A. Regarding the gate electrode 27A on the gate insulating film 25A, the end on the −X-axis direction substantially coincides with the end on the −X-axis direction of the gate insulating film 25A, and the end on the +X-axis direction substantially coincides with the +X-axis direction side end of the gate insulating film 25A. Similarly, for the gate electrode 27A on the gate insulating film 25B, the end on the −X-axis direction substantially coincides with the end on the −X-axis direction of the gate insulating film 25B, and the end on the +X-axis direction substantially coincides with the +X-axis direction side end of the insulating film 25B. The gate electrode 27A on the gate insulating film 25A and the gate electrode 27A on the gate insulating film 25B may be connected to the gate pad 16 through the same gate wiring (not shown). The gate electrode 27A on gate insulating film 25A and the gate electrode 27A on gate insulating film 25B are electrically connected.

In the semiconductor device 130, the gate insulating film 25A is in contact with the n⁺-type source region 23A, the p-type well region 22A, and the n-type drift layer 18. In semiconductor device 130, the gate insulating film 25B is in contact with n⁺-type source region 23B, p-type well region 22B, and n-type drift layer 18. Thus, in the unit cell 41A, the gate insulating film on the upper surface of the channel portion 44A of the MOSFET portion 42A is the gate insulating film 25A, and the gate insulating film on the upper surface of the channel portion 45A of the MOSFET portion 43A is the gate insulating film 25B.

In the semiconductor device 130 of the fourth embodiment, the gate insulating film 25A is provided on the channel portion 44 and the gate insulating film 25B is provided on the channel portion 45. Therefore, as in the first embodiment, the MOSFET section 42 and the MOSFET section 43 have different thresholds, making it possible to adjust the di/dt characteristics. In addition, in the semiconductor device 130 of the fourth embodiment, the gate insulating film 25A and the gate insulating film 25B are divided by the interlayer insulating film 28A. As a result, the gate-drain capacitance is reduced compared to the semiconductor device 100.

The manufacturing method of the semiconductor device 130 of the fourth embodiment differs from the semiconductor device 100 of the first embodiment in that when the gate insulating film 26A and the gate electrode 27A are processed by photolithography and etching, the corresponding vicinity of the step portion C is also removed. Because the other steps are the same, the description thereof is omitted.

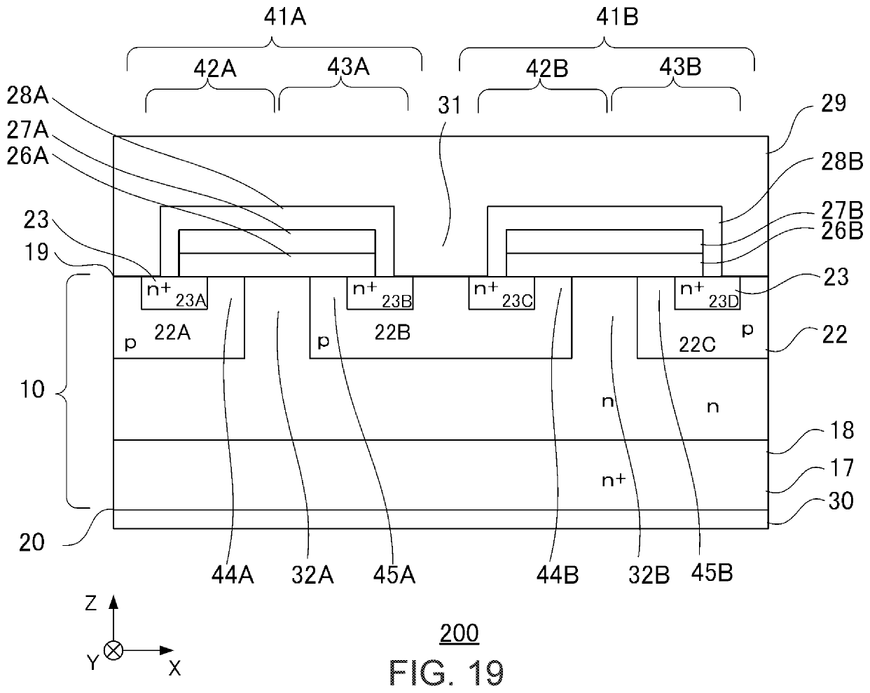

FIG. 19 is a diagram explaining a comparative example. In the semiconductor device 200 of the comparative example, the film thickness of the gate insulating film is uniform. That is, the MOSFET section 42A and the MOSFET section 43A in the unit cell 41A have the same gate insulating film thickness. Similarly, the MOSFET section 42B and the MOSFET section 43B in the unit cell 41B have the same gate insulating film thickness. Also, the gate insulating films 26A and 26B have the same film thickness. In this example, the thickness of the gate insulating films 26A and 26B may be the same as the thickness of the gate insulating film 25A of the semiconductor device 100 of the first embodiment.

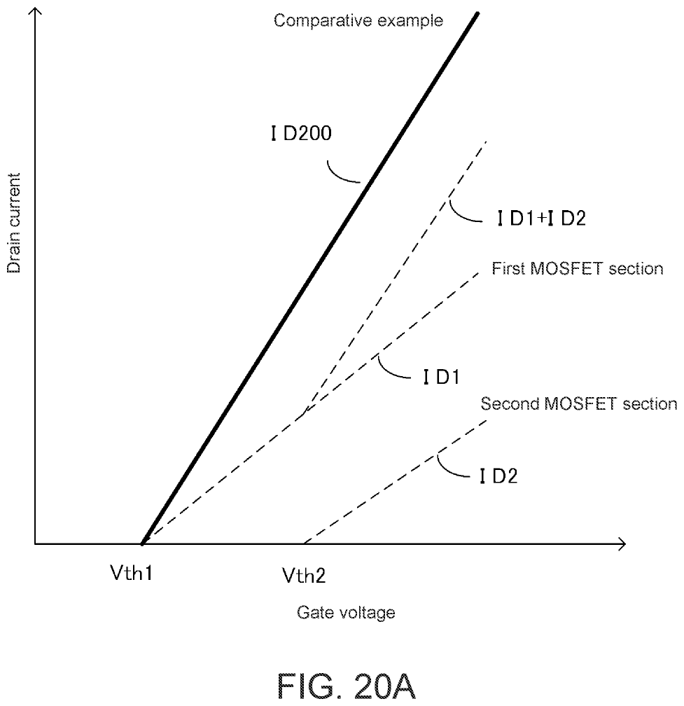

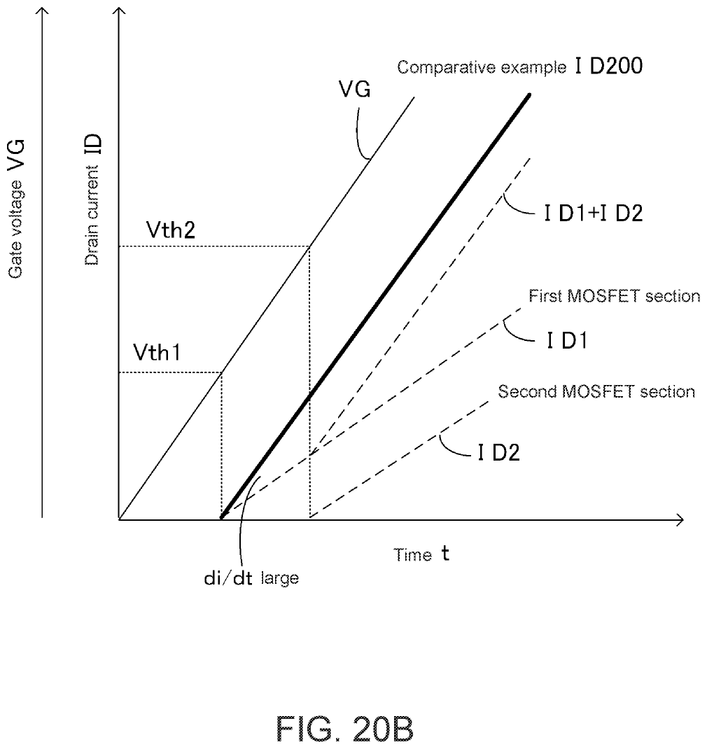

FIG. 20A is a diagram showing the relationship between the gate voltage and the drain current of the semiconductor device 200. The dotted line indicates the relationship between the gate voltage and the drain current in the first embodiment shown in FIG. 3A, and the solid line indicates the relationship between the gate voltage and the drain current in the comparative example. In the semiconductor device 200, the threshold voltage Vth1 of the MOSFET section 42A and the MOSFET section 43A is determined by the film thickness of the gate insulating film 26A and the like, is the same threshold voltage Vth1.

The film thickness of the gate insulating film 26 of the semiconductor device 200 is the same as the film thickness of the gate insulating film 25A of the MOSFET section 42A of the semiconductor device 100. In the semiconductor device 200, since the same gate voltage is applied to the MOSFET sections 42A and 43A, the drain current ID200 begins to flow through the MOSFET sections 42A and 43A at the same time when the gate voltage exceeds Vth1. Therefore, the entire semiconductor device 200 is turned on, and a drain current twice that of ID1 in the first embodiment flows.

FIG. 20B is a diagram showing the relationship between drain current and time. The relationship between the drain current and time in the first embodiment shown in FIG. 3B is indicated by the dotted line, and the relationship between the drain current and time in the comparative example is indicated by the solid line. FIG. 20B also shows the gate voltage VG. When the gate voltage VG exceeds Vth1, the drain current ID1 begins to flow in the MOSFET section 42A and the MOSFET section 43A. Therefore, in the semiconductor device 200, when the gate voltage VG exceeds Vth1, a drain current twice as large as ID1 in the first embodiment begins to flow. Therefore, in the semiconductor device 200, the current slope (solid line) when the gate voltage VG exceeds Vth1 is larger than the current slope (dotted line) of the semiconductor device 100, and di/dt is large. When the density of the unit cell 41 is improved by miniaturization in order to reduce the on-resistance of the MOSFET, a large di/dt at the time of turn-on also increases the gain characteristics, so there is a risk of electromagnetic interference (noise), as mentioned above. As described above, such undesired noise is suppressed efficiently and efficiently in the embodiments of the present invention.

In this example, the case of a vertical MOSFET is shown, but in the case of a vertical IGBT, in regard to the problem of a reduction in short-circuit withstand capability, by locally and partially increasing the gate insulating film thickness, the saturation current can be suppressed, the short-circuit current when the IGBT is short-circuited is lowered, and the short-circuit withstand capability can be improved.

Although the present invention has been described above with reference to the embodiments, it will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

The execution order of each process such as actions, procedures, steps, and stages in the devices, systems, programs, and methods shown in the claims, the specification, and the drawings is not particularly limited and can be implemented in any order unless the expressions, such as “before”, “in advance of” or like language, are used or the output of the previous process is used in the subsequent process. Regarding the operation flow in the claims, the specification, and the drawings, even if the description is made using “first,” “next,” etc., that does not necessarily mean that it is essential to carry out the described things in that order.

What is claimed is:

1. A semiconductor device, comprising:
a semiconductor substrate having an upper surface and a lower surface, the semiconductor substrate including:
a drift layer on a side of the upper surface and a drain layer on a side of the lower surface,
a first well region and a second well region selectively formed in the drift layer, each extending downwardly from the upper surface of the semiconductor substrate up to a first depth within the drift layer, the first well region and the second well region being arranged side by side with a portion of the drift layer sandwiched therebetween at the upper surface of the semiconductor substrate,
a first source region selectively formed in the first well region so as to extend downwardly from the upper surface of the semiconductor substrate up to a second prescribed depth within the first well region, and
a second source region selectively formed in the second well region so as to extend downwardly from the upper surface of the semiconductor substrate up to the second depth within the second well region;
a gate insulating film selectively disposed on the upper surface of the semiconductor substrate, the gate insulating film covering the portion of the drift layer sandwiched by the first well region and the second well region, and having a first portion and a second portion arranged side by side so as to be laterally continuous to each other, the first portion being thinner than the second portion and arranged on, and in direct contact with, the first well region and the first source region, the second portion being arranged on, and in direct contact with, the second well region and the second source region; and
a gate electrode disposed on the gate insulating film that includes the first and second portions.

2. The semiconductor device according to claim 1, wherein the first portion and the second portion of the gate insulating film are both on the portion of the drift layer sandwiched by the first and second well regions.

3. The semiconductor device according to claim 1, wherein the second portion of the gate insulating film covers a substantially entirety of the portion of the drift layer sandwiched by the first and second well regions.

4. A semiconductor device, comprising:
a semiconductor substrate having an upper surface and a lower surface, the semiconductor substrate including:
a drift layer on a side of the upper surface and a drain layer on a side of the lower surface,
a first well region and a second well region selectively formed in the drift layer, each extending downwardly from the upper surface of the semiconductor substrate up to a first depth within the drift layer, the first well region and the second well region being arranged side by side with a portion of the drift layer sandwiched therebetween at the upper surface of the semiconductor substrate,
a first source region selectively formed in the first well region so as to extend downwardly from the upper surface of the semiconductor substrate up to a second depth within the first well region, and
a second source region selectively formed in the second well region so as to extend downwardly from the upper surface of the semiconductor substrate up to the second depth within the second well region;
a gate insulating film selectively disposed on the upper surface of the semiconductor substrate, the gate insulating film having a first portion and a second portion arranged side by side laterally separated from each other, the first portion being thinner than the second portion and arranged on, and in direct contact with, the first well region and the first source region, the second portion being arranged on, and in direct contact with, the second well region and the second source region; and
a first gate electrode disposed on the first portion of the gate insulating film and a second gate electrode disposed on the second portion of the gate insulating film.

5. The semiconductor device according to claim 1, wherein a film thickness of the second portion of the gate insulating film is 1.3 to 2 times a film thickness of the first portion of the gate insulating film.

6. The semiconductor device according to claim 4, wherein a film thickness of the second portion of the gate insulating film is 1.3 to 2 times a film thickness of the first portion of the gate insulating film.

7. A method for manufacturing a semiconductor device in a semiconductor substrate having an upper surface and a lower surface and including a drift layer on a side of the upper surface and a drain layer on a side of the lower surface, the method comprising:
selectively forming well regions in the drift layer in the semiconductor substrate each extending downwardly from the upper surface of the semiconductor substrate up to a first depth within the drift layer;
selectively forming source regions in the well regions, respectively, each extending downwardly from the upper surface of the semiconductor substrate up to a second depth within the corresponding well regions;
forming a gate insulating film on the upper surface of the semiconductor substrate, the gate insulating film having a first portion and a second portion that are arranged laterally, the first portion being thinner than the second portion;
forming a gate electrode on an upper surface of the gate insulating film;
forming an interlayer insulating film so as to cover the gate electrode;
forming a source electrode on an upper surface of the interlayer insulating film; and
forming a drain electrode on the lower surface of the semiconductor substrate.

8. The method according to claim 7, wherein the forming the gate insulating film includes:
forming an insulating film on an entirety of the upper surface of the semiconductor substrate;
selectively removing prescribed portions of the insulating film to form a pattern of the insulating films on the upper surface of the semiconductor substrate; and
thereafter forming another insulating film on the pattern of the insulating films and on the upper surface of the semiconductor substrate on which the insulating film has been removed, thereby forming a composite insulating film as the gate insulating film having the first portion and the second portion that is thicker than the first portion.
